(19) United States
(12) Patent Application Publication
(10) Pub. No.: US 2015/0221836 A1
(43) Pub. Date: Aug. 6, 2015

(54) OPTICAL SEMICONDUCTOR LIGHT EMITTING DEVICE, LIGHTING APPARATUS, AND DISPLAY DEVICE

(71) Applicant: SUMITOMO OSAKA CEMENT CO., LTD., Chiyoda-ku, Tokyo (JP)

(72) Inventors: Yasuyuki Kurino, Chiyoda-ku (JP); Takeshi Otsuka, Chiyoda-ku (JP); Yoichi Sato, Chiyoda-ku (JP); Takeru Yamaguchi, Chiyoda-ku (JP); Kenji Harada, Chiyoda-ku (JP)

(73) Assignee: Sumitomo Osaka Cement Co., Ltd., Chiyoda-ku, Tokyo (JP)

(21) Appl. No.: 14/424,957

(22) PCT Filed: Aug. 26, 2013
(86) PCT No.: PCT/JP2013/072777

§ 371 Date: Feb. 27, 2015

(30) Foreign Application Priority Data
Aug. 28, 2012 (JP) 2012-187896

(51) Int. Cl. H01L 33/50; H01L 33/58

(52) U.S. Cl. CPC H01L 33/507; H01L 33/58; H01L 2933/0091

(57) ABSTRACT

An optical semiconductor light emitting device which emits white light, includes: an optical semiconductor light emitting element; and an optical conversion layer containing phosphor particles, in which a specific light scattering composition is contained in the optical conversion layer or a light scattering layer containing a specific light scattering composition is provided on the optical conversion layer. An illumination apparatus and a display apparatus including the same are also provided.

### BACKGROUND OF THE INVENTION

1. Field of the Invention

The present invention relates to an optical semiconductor light emitting device, and an illumination apparatus and a display apparatus including the same.

2. Description of Related Art

In a white optical semiconductor light emitting device having a blue optical semiconductor light emitting element and a phosphor which are combined with each other, white light (pseudo-white) is obtained by combining blue light emitted from the blue optical semiconductor light emitting element and light of which the wavelength is converted by the phosphor. As this type of white optical semiconductor light emitting device, there are a type in which a blue optical semiconductor light emitting element and a yellow phosphor are combined with each other and a type in which a blue optical semiconductor light emitting element, a green phosphor, and a red phosphor are combined with each other. However, the light source (the color of light emitted by the optical semiconductor light emitting element) emits blue light, and thus the white light primarily includes blue components. Particularly, the white optical semiconductor light emitting device in which the blue optical semiconductor light emitting element and the yellow phosphor are combined with each other extremely significantly includes the blue components.

Since the white optical semiconductor light emitting device in which the blue optical semiconductor light emitting element and the phosphor are combined with each other primarily includes the blue components, retinal diseases of the eye due to the blue light, physiological damage to the skin, physiological influences on the level of awakening, autonomic nervous function, body clock, melatonin secretion, and the like are pointed out. In addition, recently, there is a growing market for optical semiconductor light emitting devices for illumination use, and thus the development of optical semiconductor light emitting devices with higher luminance is progressing. Therefore, the human body is increasingly exposed to blue light.

In order to provide a scattering site in the optical semiconductor light emitting device, a planar light source (Japanese Patent No. 3116727) in which light in a light guide plate is scattered by a scattering layer to which white powder is applied so as to provide a constant surface luminance, a method (PCT Japanese Translation Patent Publication No. 2003-515899) of scattering light that passes through a light source to be converged, directed, and converted and radially dispersing white light to be used for indoor illumination uses, a method (Japanese Laid-open Patent Publication No. 2007-317659) of allowing a sealing material to contain diffusing particles that scatter light in order to remove dark spots of LED devices adjacent to each other, and a method (Japanese Laid-open Patent Publication No. 2011-150790) of reducing color unevenness in illumination light by causing scattering particles having a particle size of 2 μm to 4.5 μm to coexist with a phosphor in a sealing material are proposed. In addition, a method (PCT Japanese Translation Patent Publication No. 2007-507089) of disposing a filter element having a large number of nanoparticles on a rear side of a luminescence conversion element and selectively reducing a radiation intensity in at least one spectrum partial region of undesired radiation through absorption is proposed.

However, the object of all of the proposals is for uniformizing the distribution of light emitted from the optical semiconductor light emitting device to the outside or for reducing color unevenness, but is not for reducing a blue light component of light emitted to the outside. In addition, with the particle size of Japanese Laid-open Patent Publication No. 2011-150790, the transparency of light emitted from an optical semiconductor light emitting element is reduced, and there is a problem in that the luminance of the optical semiconductor light emitting device is reduced. In addition, in a case where the intensity of the undesired radiation is reduced through absorption as in PCT Japanese Translation Patent Publication No. 2007-507089, the luminance of the optical semiconductor light emitting device is reduced, and thus there is a problem in that radiation is converted to heat through absorption and thus the peripheral materials may be damaged or the light emission efficiency of the optical semiconductor light emitting element may be reduced due to the heat.

### SUMMARY OF THE INVENTION

Accordingly, an object of the present invention is to provide an optical semiconductor light emitting device capable of reducing a blue light component emitted along with white light and enhancing the luminance, and an illumination apparatus and a display apparatus including the same.

The inventors intensively studied to solve the problems, and as a result, found that by causing an optical conversion layer containing phosphor particles to contain a specified light scattering composition or providing a light scattering layer containing a specified light scattering composition on an optical conversion layer, the optical semiconductor light emitting device capable of reducing a blue light component emitted along with white light and enhancing the luminance can be obtained, and invented the present invention. That is, the present invention is described as follows.

[1] An optical semiconductor light emitting device which emits white light, including: an optical semiconductor light emitting element; and an optical conversion layer containing phosphor particles, in which the optical conversion layer further includes a light scattering composition containing light scattering particles and a binder, and the light scattering particles are particles having an average primary particle size of 3 nm or greater and 20 nm or smaller, which are surface-modified by a surface modifying material having one or more of functional groups selected from an alkenyl group, an H—Si group, and an alkoxy group, and are made of a material which does not absorb light in an optical semiconductor emission wavelength region.

[2] An optical semiconductor light emitting device which emits white light, including: an optical semiconductor light emitting element; and an optical conversion layer containing phosphor particles, in which a light scattering layer which includes a light scattering composition containing light scattering particles and a binder is provided on the optical conversion layer, and the light scattering particles are particles having an average primary particle size of 3 nm or greater and 20 nm or smaller, which are surface-modified by a surface modifying material having one or more of functional groups selected from an alkenyl group, an H—Si group, and an alkoxy group, and are made of a material which does not absorb light in an optical semiconductor emission wavelength region.

[3] The optical semiconductor light emitting device described in [1] or [2], in which the light scattering composition has a transmittance of 40% or higher and 95% or lower at a wavelength of 460 nm and a transmittance of 80% or higher at a wavelength of 550 nm, the transmittance being measured by an integrating sphere.

[4] An illumination apparatus including: the optical semiconductor light emitting device described in any one of [1] to [3].

[5] A display apparatus including: the optical semiconductor light emitting device described in any one of [1] to [3].

According to the present invention, the optical semiconductor light emitting device capable of reducing a blue light component emitted along with white light and enhancing the luminance, and the illumination apparatus and the display apparatus including the same can be provided. In addition, since the blue light component is reduced, color rendering properties can also be enhanced.

### BRIEF DESCRIPTION OF THE DRAWINGS

FIG. 1 is a schematic cross-sectional view illustrating an example of an optical semiconductor light emitting device of the present invention.

FIG. 2 is a schematic cross-sectional view illustrating another example of the optical semiconductor light emitting device of the present invention.

FIG. 3 is a schematic cross-sectional view illustrating another example of the optical semiconductor light emitting device of the present invention.

FIG. 4 is a schematic cross-sectional view illustrating another example of the optical semiconductor light emitting device of the present invention.

### DETAILED DESCRIPTION OF THE INVENTION

### [Optical Semiconductor Light Emitting Device]

An optical semiconductor light emitting device of the present invention is an optical semiconductor light emitting device which emits white light, including: an optical semiconductor light emitting element; and an optical conversion layer containing phosphor particles (simply referred to as “phosphors”), and is (A) an optical semiconductor light emitting device (hereinafter, referred to as an “optical semiconductor light emitting device A”) in which the optical conversion layer further includes a light scattering composition containing light scattering particles and a binder, and the light scattering particles are particles having an average primary particle size of 3 nm or greater and 20 nm or smaller, which are surface-modified by a surface modifying material having one or more of functional groups selected from an alkenyl group, an H—Si group, and an alkoxy group, and do not absorb light in an optical semiconductor emission wavelength region. In addition, the optical semiconductor light emitting device of the present invention is (B) an optical semiconductor light emitting device (hereinafter, referred to as an “optical semiconductor light emitting device B”) in which a light scattering layer which includes a light scattering composition containing light scattering particles and a binder is provided on the optical conversion layer, and the light scattering particles are the same particles as those of the optical semiconductor light emitting device A.

In addition, in the description of the present invention, when the “optical semiconductor light emitting device” is simply mentioned, it indicates both the “optical semiconductor light emitting device A” and the “optical semiconductor light emitting device B”.

Examples of the combination of an optical semiconductor light emitting element and a phosphor in the optical semiconductor light emitting device of the present invention include: the combination of a blue optical semiconductor light emitting element having an emission wavelength of about 460 nm and a yellow phosphor; the combination of a blue optical semiconductor light emitting element having an emission wavelength of about 460 nm, a red phosphor, and a green phosphor; the combination of a near-ultraviolet optical semiconductor light emitting element having an emission wavelength of about 340 nm to 410 nm and phosphors of three primary colors including a red phosphor, a green phosphor, and a blue phosphor; and the like. In this case, as various semiconductor light emitting elements and various phosphors, well-known semiconductor light emitting elements and phosphors may be used.

In addition, as a sealing resin for sealing various semiconductor light emitting elements or various phosphors, a well-known sealing resin may be used.

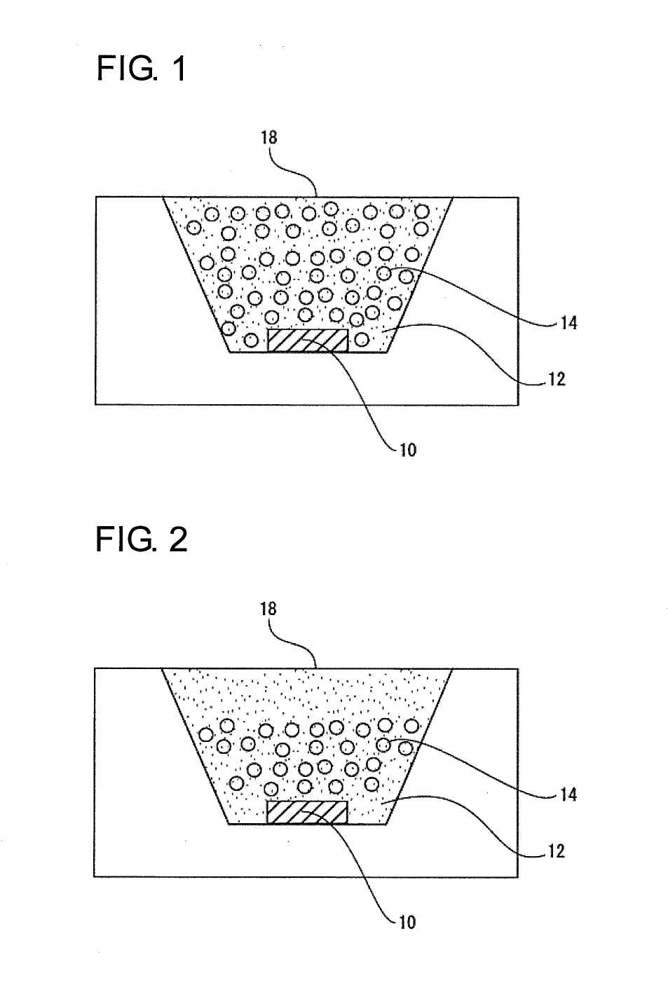

Embodiments of the optical semiconductor light emitting devices A and B of the present invention will be described with reference to FIGS. 1 to 4.

First, in a first embodiment of the optical semiconductor light emitting device A of the present invention, as illustrated in FIG. 1, an optical semiconductor light emitting element 10 is disposed in a recessed portion of a substrate, and an optical conversion layer 12 containing phosphor particles 14 and a light scattering composition that contains light scattering particles and a binder is provided to cover the optical semiconductor light emitting element 10. At this time, it is preferable that the light scattering particles are present closer to an outside air phase interface 18 side than the phosphor particles. The surface shape of the outside air phase interface 18 is not particularly limited, and may be any of a flat shape, a convex shape, and a concave shape.

In a second embodiment of the optical semiconductor light emitting device A of the present invention, as illustrated in FIG. 2, most of the light scattering particles are present closer to the outside air phase interface 18 side than phosphor particles compared to the case of FIG. 1. In these embodiments, a blue light component which is emitted along with white light is reduced, and thus luminance can be further enhanced.

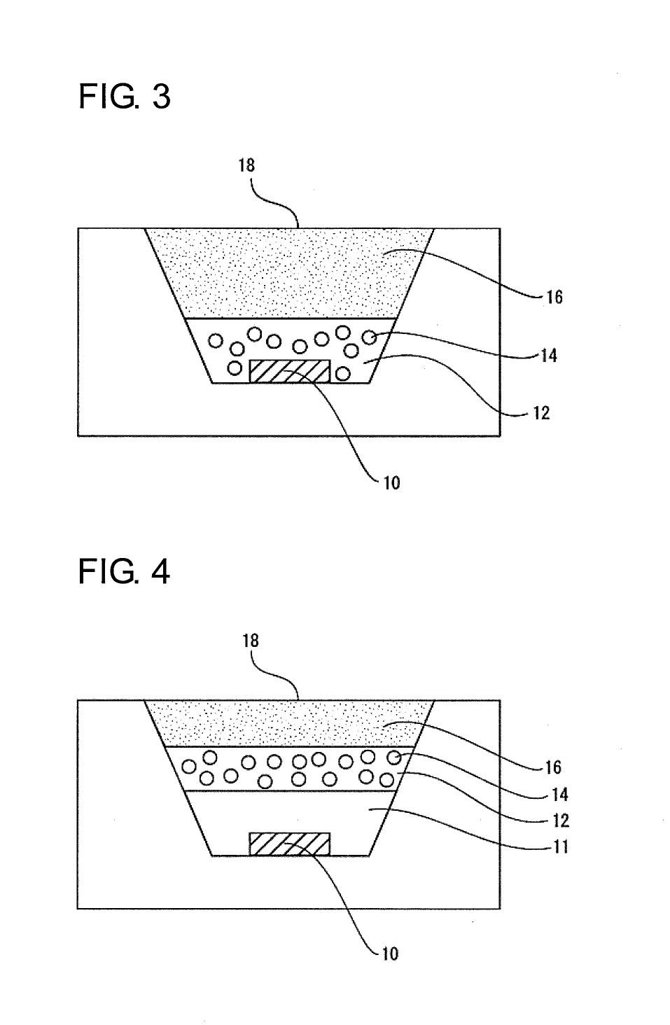

The optical semiconductor light emitting device B of the present invention is embodied such that a layer (optical conversion layer) containing the phosphor particles and a layer (light scattering layer) containing the light scattering particles are arranged to be separated from each other. In a first embodiment of the optical semiconductor light emitting device B, as illustrated in FIG. 3, the optical semiconductor light emitting element 10 is disposed in the recessed portion of the substrate, the optical conversion layer 12 containing the phosphor particles 14 is provided to cover the optical semiconductor light emitting element 10, and a light scattering layer 16 containing the above-described light scattering composition is provided on the optical conversion layer 12, that is, on the outside air phase interface 18 side of the optical conversion layer 12.

In a second embodiment of the optical semiconductor light emitting device B of the present invention, as illustrated in FIG. 4, a sealing resin layer 11 made of a sealing resin is provided to cover the optical semiconductor light emitting element 10, the optical conversion layer 12 is provided on the sealing resin layer 11, and the light scattering layer 16 is provided on the optical conversion layer 12, that is, on the outside air phase interface 18 side of the optical conversion layer 12.

In the optical semiconductor light emitting device B, the thicknesses of the optical conversion layer and the light scattering layer are not particularly limited as long as the effect of the present invention is obtained. However, in a case of further reducing the blue component, it is preferable that the thickness of the light scattering layer is further increased, and the thickness of the light scattering layer may be designed in consideration of the wavelength conversion efficiency and the addition amount of the phosphor, which are used in a case of adjusting the optical semiconductor light emitting device to have desired color rendering properties.

It is preferable that the transmittance of the light scattering composition at a wavelength of 460 nm, which is measured by an integrating sphere, is 40% or higher and 95% or lower. Since the transmittance at a wavelength of 460 nm is 40% or higher, a reduction in the transparency of the entire light is prevented, and thus the luminance of the optical semiconductor light emitting device can be enhanced. In addition, when the transmittance is 95% or lower, the color component of the light emitted by the optical semiconductor light emitting element, of which the wavelength is not converted by the phosphor, is prevented from being significantly emitted toward the outside air phase and scatters in a direction different from that of the outside air phase. Therefore, the color rendering properties of the optical semiconductor light emitting device can be enhanced. The transmittance at a wavelength of 460 nm is more preferably 45% or higher and 90% or lower, and is more preferably 50% or higher and 85% or lower.

In addition, it is preferable that the transmittance at a wavelength of 550 nm is 80% or higher. Since the transmittance is 80% or higher, a reduction in the transparency of white light which is a combination of the color of light emitted by the optical semiconductor light emitting element and light of the color of the emitted light of which the wavelength is converted by the phosphor is prevented, and thus the luminance of the optical semiconductor light emitting device can be enhanced. The transmittance at a wavelength of 550 nm is more preferably 85% or higher, and is even more preferably 90% or higher.

In order to obtain the above-described transmittance, the particle size or the amount of the light scattering particles may be adjusted.

As the light scattering particles, inorganic particles, organic resin particles, and particles obtained by dispersing inorganic particles in organic resin particles to form a composite may be employed. In consideration of facilitation of surface reforming to secure monodispersibility in the binder and interfacial affinity with the binder, inorganic particles are preferable, and metal oxide particles such as ZrO₂, TiO₂, ZnO, Al₂O₃, SiO₂, and CeO₂, which are materials that do not absorb light at a wavelength of 460 nm in the optical semiconductor emission wavelength region, are preferable. Particularly, ZrO₂ and TiO₂ having high refractive indexes are preferable because an efficiency of extracting light from the optical semiconductor light emitting element can be enhanced.

The average primary particle size of the light scattering particles is 3 nm or greater and 20 nm or smaller, is preferably 4 nm or greater and 15 nm or smaller, and is more preferably 5 nm or greater and 10 nm or smaller. When the average primary particle size is smaller than 3 nm, a scattering effect is low, and thus the scattering amount of light in a direction different from the outside air phase is reduced. Therefore, the color component of light emitted is significantly emitted toward the outside air phase. When the average primary particle size is greater than 20 nm, the scattering amount becomes too high, and thus not only the color component of the emitted light but also the component of light of which the wavelength is converted by the phosphor is not emitted toward the outside air phase. Therefore, the luminance of the optical semiconductor light emitting device is reduced.

The amount of the light scattering particles in the optical conversion layer or in the light scattering layer is preferably 10% by mass to 70% by mass, is more preferably 20% by mass to 60% by mass, and is even more preferably 30% by mass to 50% by mass. Since the amount is 10% by mass to 70% by mass, the balance between scattering properties and optical transparency is good. In addition, in a case of using the metal oxide particles ZrO₂ and TiO₂ as the light scattering particles, the refractive index can be increased, and thus the efficiency of extracting light from the optical semiconductor light emitting element can be enhanced, thereby allowing the optical semiconductor light emitting device to have higher luminance.

As the binder applied to the light scattering composition, a transparent resin may be used as long as the reliability (various required performances and durability) of the optical semiconductor light emitting device is not damaged. In a case where the application of the binder to an increase in the output of the optical semiconductor light emitting element or to the illumination use is postulated, a general optical semiconductor light emitting element sealing material is preferably used. Particularly, from the viewpoint of durability, a silicone-based sealing material is preferably used, and a dimethyl silicone resin, a methylphenyl silicone resin, a phenyl silicone resin, an organic modified silicone resin, and the like are employed. The material is cured by an addition type reaction, a condensation type reaction, or a radical polymerization reaction.

In order to uniformly disperse the light scattering particles in the binder, the interfacial affinity between the surface of the light scattering particle and the binder resin needs to be secured, and thus the particle surface is coated with a surface modifying material which has a structure compatible with the structure of the binder resin.

As the surface modifying material, a surface modifying material having one or more of functional groups selected from an alkenyl group, an H—Si group, and an alkoxy group is preferably used.

In addition, in order to further increase the interfacial affinity between the surface of the light scattering particle and the binder resin or in order to more efficiently modify the surface modifying material having the functional groups in a process of performing surface modification on the light scattering particle, a well-known surface modifying material may also be used in addition to the surface modifying material having the functional groups.

The alkenyl group is cross-linked to the H—Si group in the binder resin, the H—Si group is cross-linked to the alkenyl group in the binder resin, and the alkoxy group and the alkoxy group in the binder or the alkoxy group of the surface modifying material are hydrolyzed and condensed. In this reaction, particles can be fixed in the optical conversion layer or the light scattering layer while maintaining the dispersed state without phase separation of the particles in a process of curing the optical conversion layer or the light scattering layer, and thus denseness of such layers can be enhanced.

As the surface modifying material having one or more of functional groups selected from an alkenyl group, an H—Si group, and an alkoxy group, there are vinyltrimethoxysilane, dimethyl silicone having an alkoxy end and a vinyl end, methylphenyl silicone having an alkoxy end and a vinyl end, phenyl silicone having an alkoxy end and a vinyl end, methacryloxypropyltrimethoxysilane, acryloxypropyl trimethoxysilane, a carbon-carbon unsaturated bond-containing fatty acid such as a methacrylic acid, dimethylhydrogen silicone, methylphenylhydrogen silicone, phenylhydrogen silicone, dimethylchlorosilane, methyldichlorosilane, diethyl, chlorosilane, ethyldichlorosilane, methylphenylchlorosilane, diphenylchlorosilane, phenyldichlorosilane, trimethoxysilane, dimethoxysilane, monomethoxysilane, triethoxysilane, diethoxymonomethylsilane, monoethoxydimethylsilane, methylphenyldimethoxysilane, diphenylmonomethoxysilane, methylphenyldiethoxysilane, diphenylmonoethoxysilane, phenyl silicone having two alkoxy ends, methylphenyl silicone having two alkoxy ends, an alkoxy group-containing dimethyl silicone resin, an alkoxy group-containing phenyl silicone resin resin, and an alkoxy group-containing methylphenyl silicone resin.

The surface modification amount of the surface modifying material having one or more of functional groups selected from an alkenyl group, an H—Si group, and an alkoxy group is preferably 1% by mass or more and 80% by mass or less with respect to the mass of the metal oxide particles. Since the surface modification amount is 1% by mass or more, the number of points of bonds with the functional group contained in the binder resin is increased, phase separation of the particles in the process of curing the optical conversion layer or the light scattering layer is less likely to occur, and thus a reduction in the hardness of the cured body can be prevented. Since the surface modification amount is 80% by mass or less, the number of points of bonds with the functional group contained in the binder resin is not excessively increased. As a result, the cured body is prevented from being embrittled and causing cracking.

The surface modification amount of the surface modifying material having one or more of functional groups selected from an alkenyl group, an H—Si group, and an alkoxy group is more preferably 3% by mass or more and 70% by mass or less, and is even more preferably 5% by mass or more and 60% by mass or less.

As a method of surface modification, a dry method of directly mixing or spraying the surface modifying material to the light scattering particles and a wet method of pouring the light scattering particles into water or an organic solvent in which the surface modifying material is dissolved so as to be surface-modified in the solvent may be employed.

As a method of uniformly dispersing the surface-modified light scattering particles in the binder, there are a method of mixing the surface modifying particles with the binder in a mechanical method using a biaxial kneader or the like so as to be dispersed and a method of mixing a dispersion obtained by dispersing the surface modifying particles in an organic solvent with the binder and then drying the organic solvent.

The optical semiconductor light emitting device according to the present invention is manufactured by applying or injecting the light scattering composition obtained as described above into the optical conversion layer, or mixing the phosphor particles with the light scattering composition and applying or injecting the mixture onto the optical semiconductor light emitting element, and then curing the resultant.

### [Illumination Apparatus and Display Apparatus]

The optical semiconductor light emitting device of the present invention may be used for various uses due to its excellent properties. The effect of the present invention is particularly significantly recognized in various illumination apparatuses and display apparatuses including the optical semiconductor light emitting device.

As the illumination apparatus, general illumination apparatuses such as indoor lighting or outdoor lighting may be employed. In addition, the optical semiconductor light emitting device may also be applied to illumination of a switch unit of an electronic apparatus such as mobile phones or office automation equipment.

Examples of the display apparatus include light emitting devices in display apparatuses of instruments that particularly require high luminance and good color rendering properties while achieving a size reduction, a weight reduction, a thickness reduction, power savings, and good visibility even under sunlight, such as a mobile phone, a portable information terminal, an electronic dictionary, a digital camera, a computer, a thin television, an illumination device, and peripheral devices thereof. Particularly, a display apparatus which is viewed over a long period of time such as the display apparatus (display) of a computer or a thin television is particularly appropriate because an effect on the human body, particularly the eye can be suppressed. In addition, since a reduction in size can be achieved by causing the distance between a first light emitting element and a second light emitting element to be 3 mm or shorter, or to be close to 1 mm or shorter, a small display apparatus having a 15-inch or smaller size is also appropriate.

### EXAMPLES

Various measurement methods and evaluation methods according to this example are described as follows.

### (Measurement of Transmittance of Light Scattering Composition)

The transmittance of the light scattering composition was measured by interposing the light scattering composition between thin layer quartz cells having a size of 0.5 mm and using an integrating sphere in a spectrophotometer (V-570 manufactured by JASCO Corporation). A transmittance of 40% or higher and 95% or lower at a wavelength of 460 nm and a transmittance of 80% or higher at a wavelength of 550 nm were evaluated as “A”, and transmittances outside of the ranges were evaluated as “B”.

In addition, the thin layer quartz cells having the light scattering composition interposed therebetween were installed instead of the reflector of the spectrophotometer, a reflection spectrum which had returned from the integrating sphere was measured, and it was seen that a reduction in transmittance at short wavelengths corresponded to an increase in reflectance. From this, it was confirmed that absorption of light by particles did not occur and backscattering by particles had occurred.

### (Measurement of Average Primary Particle Size of Light Scattering Particles)

The average primary particle size of the light scattering particles was evaluated as a Scherrer size obtained by X-ray diffraction.

### (Evaluation of Emission Spectrum of Optical Semiconductor Light Emitting Device)

The emission spectrum of the optical semiconductor light emitting device was measured by using a spectral measurement apparatus (PMA-12 manufactured by Hamamatsu Photonics K.K.). When an emission spectrum peak area at a wavelength of 400 nm to 480 nm was represented by a and an emission spectrum peak area at a wavelength of 480 nm to 800 nm was represented by b, a/b which was lower than a/b of Comparative Example 1 was evaluated as “A”, and a/b which was equal to or higher than that was evaluated as “B”. In Example 4, a/b was compared to a/b of Comparative Example 2.

### (Evaluation of Luminance of Optical Semiconductor Light Emitting Device)

The luminance of the optical semiconductor light emitting device was measured by using a luminance meter (LS-110 manufactured by Konica Minolta, Inc.). In Examples 1, 2, and 3 and Comparative Examples 3, 4, and 5, a luminance which was higher than that of Comparative Example 1 was evaluated as “A”, a luminance which was equal to that was evaluated as “B”, and a luminance which was lower than that was evaluated as “C”. In Example 4, the luminance was compared to that of Comparative Example 2.

### Example 1

### Manufacture of Zirconia Particle

Dilute ammonia water obtained by dissolving 344 g of 28% ammonia water in 20 L of pure water was added to a zirconium salt solution obtained by dissolving 2615 g of zirconium oxychloride octahydrate in 40 L (liters) of pure water while being stirred, thereby preparing a zirconia precursor slurry.

An aqueous solution of sodium sulfate obtained by dissolving 300 g of sodium sulfate in 5 L of pure water was added to the slurry while being stirred, thereby obtaining a mixture. The amount of sodium sulfate added at this time was 30% by mass with respect to the equivalent zirconia value of zirconium ions in the zirconium salt solution.

The mixture was dried in the air at 130° C. for 24 hours by using a dryer, thereby obtaining a solid. The solid was crushed by an automatic mortar, and was then baked in the air at 520° C. for 1 hour by using an electric furnace.

Subsequently, the baked product was inserted into pure water and was stirred to be in a slurry form, and thereafter the added sodium sulfate was sufficiently removed by performing cleaning thereon using a centrifugal separator. Thereafter, the resultant was dried by a dryer, thereby obtaining zirconia particles having an average primary particle size of 5.5 nm.

### (Manufacture of Surface Modifying Zirconia Dispersion)

Subsequently, 82 g of toluene and 4 g of a methoxy group-containing methylphenyl silicone resin (KR9218 manufactured by Shin-Etsu Chemical Co., Ltd.) were added to 10 g of the zirconia particles and were mixed with each other. The mixture was subjected to a surface modifying treatment for 5 hours by a bead mill, and then the beads were removed. Subsequently, 4 g of vinyltrimethoxysilane (KBM1003 manufactured by Shin-Etsu Chemical Co., Ltd.) as a vinyl group-containing modifying material was added, and a modifying and dispersing treatment was performed thereon under reflux at 130° C. for 6 hours, thereby preparing a zirconia transparent dispersion.

The surface modification amount achieved by the alkenyl group-containing surface modifying material was 40% by mass with respect to the mass of the zirconia particles.

### (Manufacture of Light Scattering Composition)

7.6 g (1.5 g of A solution and 6.1 g of B solution) of trade name: 0E-6330 (manufactured by Dow Corning Toray Co., Ltd., with a refractive index of 1.53 and a mixing ratio of A solution/B solution of 1/4) as a phenyl silicone resin was added to 50 g of the zirconia transparent dispersion and was stirred, and thereafter the toluene was removed by drying under a reduced pressure, thereby obtaining a light scattering composition (a zirconia particle amount of 30% by mass) containing the surface modifying zirconia particles and the phenyl silicone resin. The transmittance thereof was evaluated.

### (Manufacture of Optical Semiconductor Light Emitting Device Including Light Scattering Layer)

A yellow phosphor (GLD(Y)-550A manufactured by GeneLite Inc.) was added to the light scattering composition to reach 20% by mass, and the resultant was mixed and defoamed by a rotation-revolution mixer. Subsequently, the phosphor-containing light scattering composition was dropped onto a light emitting element of a package including an unsealed blue optical semiconductor light emitting element. Furthermore, a light scattering composition which did not contain the phosphor was dropped onto the phosphor-containing light scattering composition, and the resultant was heated and cured at 150° C. for 2 hours. A light scattering layer was in a convex shape with respect to an outside air layer. The emission spectrum and the luminance of an optical semiconductor light emitting device were evaluated. The results are shown the following Table 1.

### Example 2

Zirconia particles having an average primary particle size of 7.8 nm were manufactured in the same manner as in Example 1 except that a temperature of 520° C. in the air set by the electric furnace during the manufacture of the zirconia particles was changed to 550° C. During the preparation of a surface modifying zirconia dispersion, vinyltrimethoxysilane of Example 1 was changed to methyldichlorosilane (LS-50 manufactured by Shin-Etsu Chemical Co, Ltd.) as an H—Si group-containing modifying material, and after heating and stirring were performed at 50° C. for 3 hours, a modifying and dispersing treatment was performed thereon under reflux at 130° C. for 3 hours, thereby preparing a zirconia transparent dispersion. The surface modification amount achieved by the H—Si group-containing surface modifying material was 40% by mass with respect to the mass of the zirconia particles. A light scattering composition and an optical semiconductor light emitting device were manufactured and evaluated in the same manner as in Example 1 except that the zirconia transparent dispersion was used. The results were shown in the following Table 1.

### Example 3

Zirconium particles having an average primary particle size of 5.5 nm were manufactured in the same manner as in Example 1. During the preparation of a surface modifying zirconia dispersion, vinyltrimethoxysilane of Example 1 was changed to tetraethoxysilane (KBE-04 manufactured by Shin-Etsu Chemical Co., Ltd.) as an alkoxy group-containing modifying material, and after heating and stirring were performed at 50° C. for 3 hours, a modifying and dispersing treatment was performed thereon under reflux at 130° C. for 3 hours, thereby preparing a zirconia transparent dispersion. The surface modification amount achieved by the alkoxy group-containing surface modifying material was 40% by mass with respect to the mass of the zirconia particles. During the preparation of a light scattering composition, 7.6 g of a condensation curing-type phenyl silicone resin (H62C manufactured by Wacker Asahikasei Silicone Co., Ltd.) was added to 50 g of the zirconia transparent dispersion and was stirred, and thereafter the toluene was removed by drying under a reduced pressure, thereby obtaining a light scattering composition (a zirconia particle amount of 30% by mass) containing the surface modifying zirconia particles and the phenyl silicone resin. The transmittance thereof was evaluated. During the preparation of an optical semiconductor light emitting device, an optical semiconductor light emitting device was manufactured and evaluated in the same manner as in Example 1 except that the light scattering composition was used. The results were shown in the following Table 1.

### Example 4

### Manufacture of Surface Modifying Silica Dispersion

50 g of a methanol solution in which 5 g of a hexanoic acid was dissolved was mixed with 50 g of a silica sol (SNOWTEX OS manufactured by Nissan Chemical Industries, Ltd.) and was stirred to obtain a slurry. The obtained slurry was dried by an evaporator to remove the solvent. In the obtained silica particle-containing dried powder, the Scherrer sizes of the silica particles were measured by X-ray diffraction. The average primary particle size thereof was 9.5 nm. In addition, 10 g of the silica particle-containing dried powder was mixed with 80 g of toluene. Subsequently, 5 g of single-end epoxy-modified silicone (X-22-173DX manufactured by Shin-Etsu Chemical Co., Ltd.) and 5 g of vinyltrimethoxysilane (KBM1003 manufactured by Shin-Etsu Chemical Co., Ltd.) as a vinyl group-containing modifying material were added, and a modifying and dispersing treatment was performed thereon under reflux at 130° C. for 6 hours. 100 g of methanol was injected into 100 g of the obtained silica transparent dispersion, and precipitates were recovered, dried, and added to allow the silica particles in toluene to occupy 10% by mass, thereby obtaining a silica transparent dispersion. 15 g (7.5 g of A solution and 7.5 g of B solution) of trade name: 0E-6336 (manufactured by Dow Corning Toray Co., Ltd., with a refractive index of 1.41 and a mixing ratio of A solution/B solution of 1/1) as a dimethyl silicone resin was added to 50 g of the silica transparent dispersion and was stirred, and thereafter the toluene was removed by drying under a reduced pressure, thereby obtaining a light scattering composition (a zirconia particle amount of 20% by mass) containing the surface modifying zirconia particles, the dimethyl silicone resin, and a reaction catalyst. The transmittance thereof was evaluated. An optical semiconductor light emitting device was manufactured and evaluated in the same manner as in Example 1 except that the light scattering composition was used. The results were shown in the following Table 1.

### Comparative Example 1

1 g of a yellow phosphor (GLD(Y)-550A manufactured by GeneLite Inc.) was added to 5 g (2.5 g of A solution and 2.5 g of B solution) of trade name: 0E-6520 (manufactured by Dow Corning Toray Co., Ltd., with a refractive index of 1.54 and a mixing ratio of A solution/B solution of 1/1) as a phenyl silicone resin, and the resultant was mixed and defoamed by a rotation-revolution mixer. Subsequently, the phosphor-containing phenyl silicone resin composition was dropped onto a light emitting element of a package including an unsealed blue optical semiconductor light emitting element. Furthermore, the phenyl silicone resin which did not contain the phosphor was dropped, and the resultant was heated and cured at 150° C. for two hours. A phenyl silicone layer which did not contain the phosphor was in a convex shape with respect to an outside air layer. The emission spectrum and the luminance of an optical semiconductor light emitting device were evaluated. The results are shown the following Table 1.

### Comparative Example 2

An optical semiconductor light emitting device was manufactured and evaluated in the same manner as in Comparative Example 1 except that the phenyl silicone resin was changed to a dimethyl silicone resin, trade name: 0E-6336 (manufactured by Dow Corning Toray Co., Ltd., with a refractive index of 1.41 and a mixing ratio of A solution/B solution of 1/1). The results are shown the following Table 1.

### Comparative Example 3

Zirconia particles having an average primary particle size of 2.1 nm were manufactured in the same manner as in Example 1 except that a temperature of 520° C. in the air set by the electric furnace during the manufacture of the zirconia particles was changed to 500° C. A light scattering composition and an optical semiconductor light emitting device were manufactured and evaluated in the same manner as in Example 1 except that the zirconia particles were used. The results were shown in the following Table 1.

### Comparative Example 4

Zirconia particles having an average primary particle size of 21.1 nm were manufactured in the same manner as in Example 1 except that a temperature of 520° C. in the air set by the electric furnace during the manufacture of the zirconia particles was changed to 620° C. A light scattering composition and an optical semiconductor light emitting device were manufactured and evaluated in the same manner as in Example 1 except that the zirconia particles were used. The results were shown in the following Table 1.

### Comparative Example 5

Zirconium particles having an average primary particle size of 5.5 nm were manufactured in the same manner as in Example 1. During the preparation of a surface modifying zirconia dispersion, vinyltrimethoxysilane of Example 1 was changed to a stearic acid as a modifying material which did not contain a vinyl group and an H—Si group, heating and stirring were performed at 50° C. for 3 hours, and a modifying and dispersing treatment was performed on the resultant, thereby preparing a zirconia transparent dispersion. A light scattering composition and an optical semiconductor light emitting device were manufactured and evaluated in the same manner as in Example 1 except that the zirconia transparent dispersion was used. The results were shown in the following Table 1.

TABLE 1

| | | | Average | Functional | | | | | |
|---|---|---|---|---|---|---|---|---|---|
| | | | primary | group of | Transmittance of light scattering | | | Emission | |
| | | Light | particle | surface | composition | | | spectrum | |
| | | scattering | size | modifying | Wavelength | Wavelength | Evaluation of | peak area | |
| | | particles | [nm] | material | 460 [nm] | 550 [nm] | transmittance | ratio | Luminance |
| Examples | 1 | ZrO₂ | 5.5 | Alkenyl | 85 | 91 | A | A | A |
| | | | | group | | | | | |
| | 2 | ZrO₂ | 7.8 | H-Si | 76 | 86 | A | A | A |
| | | | | group | | | | | |
| | 3 | ZrO₂ | 5.5 | Alkoxy | 82 | 90 | A | A | A |
| | | | | group | | | | | |
| | 4 | SiO₂ | 9.5 | Alkoxy | 87 | 93 | A | A | B |
| | | | | group | | | | | |
| Comparative | 1 | Absent | — | — | 98 | 99 | B | 0.32 | 6200 |
| Examples | | | | | | | | | [cd/m²] |
| | 2 | Absent | — | — | 99 | 99 | B | 0.32 | 5800 |
| | | | | | | | | | [cd/m²] |
| | 3 | ZrO₂ | 2.1 | Alkenyl | 97 | 98 | B | B | A |
| | | | | group | | | | | |
| | 4 | ZrO₂ | 21.1 | Alkenyl | 21 | 45 | B | B | C |
| | | | | group | | | | | |
| | 5 | ZrO₂ | 5.5 | Alkyl | 38 | 72 | B | B | C |
| | | | | group | | | | | |

According to Table 1, in all of the optical semiconductor light emitting devices of Examples 1 to 4, the emission spectrum peak area ratios were excellent compared to those of Comparative Examples. That is, in the optical semiconductor light emitting devices of Examples 1 to 4, a blue light component which is emitted along with white light was reduced. Furthermore, all of the optical semiconductor light emitting devices of Examples 1 to 4 had high luminance, and particularly, the optical semiconductor light emitting devices of Examples 1 to 3 showed very high luminance.

### REFERENCE SIGNS LIST

10 optical semiconductor light emitting element
11 sealing resin layer
12 optical conversion layer
14 phosphor particles
16 light scattering layer
18 interface with outside air layer

1. An optical semiconductor light emitting device which emits white light, comprising:
an optical semiconductor light emitting element; and
an optical conversion layer containing phosphor particles,
wherein the optical conversion layer further includes a light scattering composition containing light scattering particles and a binder, and
the light scattering particles are particles having an average primary particle size of 3 nm or greater and 20 nm or smaller, which are surface-modified by a surface modifying material having one or more of functional groups selected from an alkenyl group, an H—Si group, and an alkoxy group, and are made of a material which does not absorb light in an optical semiconductor emission wavelength region.

2. An optical semiconductor light emitting device which emits white light, comprising:
an optical semiconductor light emitting element; and
an optical conversion layer containing phosphor particles,
wherein a light scattering layer which includes a light scattering composition containing light scattering particles and a binder is provided on the optical conversion layer, and
the light scattering particles are particles having an average primary particle size of 3 nm or greater and 20 nm or smaller, which are surface-modified by a surface modifying material having one or more of functional groups selected from an alkenyl group, an H—Si group, and an alkoxy group, and are made of a material which does not absorb light in an optical semiconductor emission wavelength region.

3. The optical semiconductor light emitting device according to claim 1,
wherein the light scattering composition has a transmittance of 40% or higher and 95% or lower at a wavelength of 460 nm and a transmittance of 80% or higher at a wavelength of 550 nm, the transmittance being measured by an integrating sphere.

4. An illumination apparatus comprising:
the optical semiconductor light emitting device according to claim 1.

5. A display apparatus comprising:
the optical semiconductor light emitting device according to claim 1.

6. The optical semiconductor light emitting device according to claim 2,
wherein the light scattering composition has a transmittance of 40% or higher and 95% or lower at a wavelength of 460 nm and a transmittance of 80% or higher at a wavelength of 550 nm, the transmittance being measured by an integrating sphere.

7. An illumination apparatus comprising:
the optical semiconductor light emitting device according to claim 2.

8. A display apparatus comprising:
the optical semiconductor light emitting device according to claim 2.
